(19) United States
(12) Patent Application Publication
(10) Pub. No.: US 2003/0051867 A1
(43) Pub. Date: Mar. 20, 2003

(54) High heat flux heat sink and method of creating same

(76) Inventor: Paul S. Kennedy, Worcester, MA (US)

Correspondence Address: Brian M. Dingman, Esq., Mirick, O'Connell, DeMallie & Lougee, LLP, 100 Front Street, Worcester, MA, 01608, US

(21) Appl. No.: 09/956,530

(22) Filed: Sep. 19, 2001

(51) Int. Cl. F28F 7/00; H05K 7/20; H01L 23/34

(52) U.S. Cl. 165/185; 257/720; 361/704

(57) ABSTRACT

A heat sink with improved thermal performance, and method of making the heat sink. The heat sink comprises a heat sink of a material with a first conductivity, and one or more inserts molded into the heat sink, and of a material with higher thermal conductivity.

### FIELD OF THE INVENTION

This invention relates to a heat sink with improved thermal performance.

### BACKGROUND OF THE INVENTION

Heat sinks are used to cool a device. For electronic components such as computer chips, a particular maximum operating temperature must be maintained. Heat dissipation can thus be a limiting factor in the design of devices employing such components. A primary problem in these applications is the need to draw heat away from the component at a rate sufficient to maintain the proper component operating temperature. If this rate cannot be maintained, the heat sink will be ineffective, regardless of its ultimate heat dissipation capacity.

### SUMMARY OF THE INVENTION

This invention relates to a heat sink that provides one or more point source (i.e., relatively small area) inserts of material(s) with a higher thermal conductivity than the rest of the heat sink, to improve the thermal performance of the heat sink. Particularly, this improves the rate at which heat can be drawn away from the component. In a specific embodiment, the heat sink is cast of aluminum, or an aluminum alloy. Other materials from which heat sinks are made (e.g. magnesium) are also contemplated herein. One or more copper pieces (or other high conductivity material, e.g. alloys or composite materials) are inserted into the die before casting of the aluminum, and are thereby insert molded into the heat sink. The insert(s) should remain solid, or at least substantially solid, at the casting temperature, so that the insert remains essentially intact. The result is that the insert(s) transfer more heat into the heat sink, thereby increasing the heat transfer rate away from the component, and the heat transfer capacity of the sink. The interface between the insert(s) and the heat sink can be accomplished as a mechanical bond or a metallurgical bond. A mechanical bond is typically sufficient, and is the preferred embodiment. If the materials themselves will not form a metallurgical bond, and a metallurgical bond is desired, the insert(s) can be coated or plated with another material that forms a metallurgical bond with both the insert material and the heat sink material. In the case of copper and aluminum, such material could be zinc.

This invention features an improved heat sink, comprising: a heat sink of a material with a first conductivity; and one or more inserts molded into the heat sink, and of a material with higher thermal conductivity.

The heat sink may be aluminum or an alloy thereof. At least one insert may be copper or an alloy thereof. The heat sink may further include one or more mechanical fasteners fastening at least one insert to the heat sink, to improve the mechanical bond there between. The molding may take place at a molding temperature, in which case the one or more inserts may be made from a material that is at least substantially solid at the molding temperature. At least one insert may define one or more projections along a surface that meets the heat sink. At least one insert may lie at a surface of the heat sink.

In a more specific embodiment, this invention features an improved heat sink, comprising: a heat sink of aluminum or an aluminum alloy; and one or more inserts of copper or a copper alloy molded into the heat sink.

Also featured is a method of molding a heat sink with improved thermal performance, wherein the molding takes place at a molding temperature, comprising: providing a molding cavity that defines the heat sink; inserting into the cavity one or more inserts of a material with a relatively high conductivity and that is at least substantially solid at the molding temperature; providing into the cavity with the one or more inserts a molten heat sink material having a conductivity lower than that of the one or more inserts; and allowing the molten material to cool and harden, to create the heat sink.

At least one insert may lie at a surface of the heat sink. The heat sink material may be aluminum or an alloy thereof. The insert material may be copper or an alloy thereof. At least one insert may define one or more projections along a surface that meets the heat sink.

### BRIEF DESCRIPTION OF THE DRAWINGS

Other objects, features and advantages will occur to those skilled in the art from the following description of the preferred embodiments and the accompanying drawings in which:

FIG. 1 is a schematic, cross-sectional view of a heat sink embodying several different aspects of this invention; and

FIG. 2 is a cross-sectional view of an alternative heat sink of the invention.

### DETAILED DESCRIPTION OF THE PREFERRED EMBODIMENTS

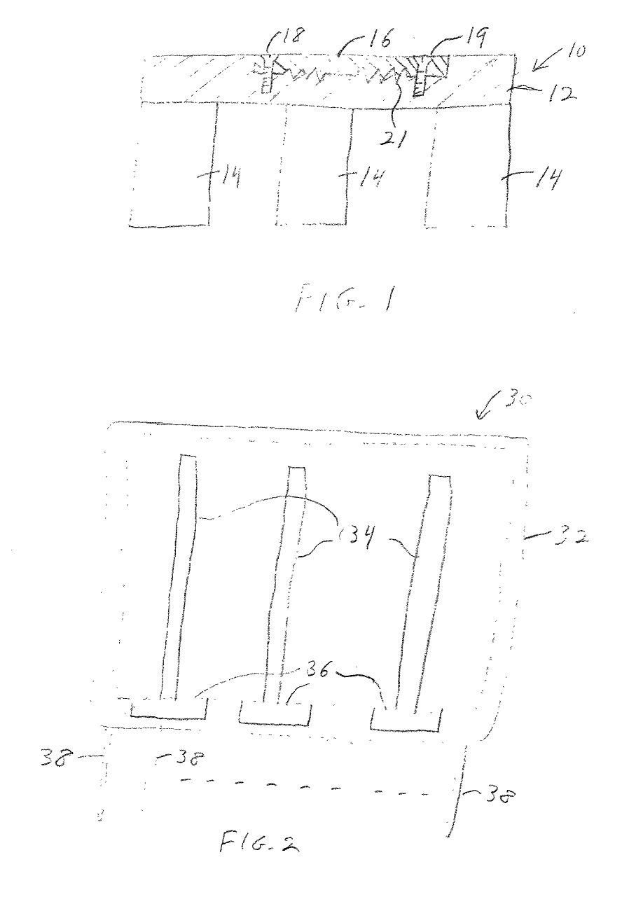

FIG. 1 shows in cross section heat sink 10 of this invention, including base 12 and projecting fins or pins 14. Insert 16 is insert molded in an area of the heat sink that will experience particularly high heat loads, for example the area that contacts the processor chip of a computer mother board. Insert 16 is of a material that has a higher conductivity that that of the base. Typically, in an electronic system heat sink, the base and fins are of aluminum or an alloy thereof, in which case copper or an alloy thereof is an ideal insert material. Other high conductivity materials, particularly metals and alloys thereof, can be used. Silver and gold would work well.

With chips running at very high speeds of a gigahertz or more, the heat loan can be too high for efficient removal by a traditional heat sink. The copper insert will conduct heat away from the chip at a higher rate due to its higher thermal conductivity. This moves heat more quickly to the body of the heat sink, from which it is then dissipated. The insert thus improves the overall thermal transfer efficiency of the improved heat sink.

The insert(s) can be of any desired thickness or shape. For insert molding, it is expected that the insert needs to be at least about 0.040″ thick in order to be handled properly in an insert molding process, while the maximum thickness can be as desired for the particular application. The preferred location of the insert(s) is at the thermal input and/or exit interfaces of the heat sink. The heat sink can be created in any convenient casting process, including die casting, molding using a permanent or sand mold, or investment casting, for example.

In one example, an aluminum heat sink was used to draw heat away from a computer chip, which operated at about 80° C. When a copper insert was molded into the heat sink, the temperature dropped to about 60° C.

Because copper and aluminum have different coefficients of thermal expansion, the mechanical bond between the insert and the heat sink changes as their temperatures change. This drawback can be addressed in a number of ways. One is to create a high surface area on the insert, by creating teeth or other projections/depressions 21 on at least one surface that is in contact with the heat sink body, as shown in the drawing. Since the aluminum is cast in the liquid state, it conforms closely to the insert surface, which is of a material that remains at least substantially solid at the molding temperature. The projections/non-linear surface at the liquid/solid interface also provides more contact area between the insert and the heat sink, which accomplishes better heat transfer from the insert into the sink, thus improving overall heat transfer performance.

Another way to overcome the expansion mismatch is to hold the insert to the heat sink with screws or other mechanical fasteners 18, 19 that counteract, at least partially, the different rates of expansion of the materials. Mechanical fasteners are typically not needed, though, as good mechanical bonding is achieved without the screws.

More than one insert can be used as shown in FIG. 2, in which enclosure 30 houses electronic components mounted on cards 34. Inserts 36 are shown in the areas of the box/heat sink 32 where printed circuit cards 34 contact the sink, to improve the thermal performance of the heat sink. Pins or fins 38 dissipate the heat into the air.

Other embodiments will occur to those skilled in the art and are within the following claims:

What is claimed is:

1. An improved heat sink, comprising:
a heat sink of a material with a first conductivity; and
one or more inserts molded into the heat sink, and of a material with higher thermal conductivity.

2. The improved heat sink of claim 1, wherein the heat sink is aluminum or an alloy thereof.

3. The improved heat sink of claim 1, wherein at least one insert is copper or an alloy thereof.

4. The improved heat sink of claim 1, further including one or more mechanical fasteners fastening at least one insert to the heat sink, to improve the mechanical bond there between.

5. The improved heat sink of claim 1, wherein the molding takes place at a molding temperature, and wherein the one or more inserts are made from a material that is at least substantially solid at the molding temperature.

6. The improved heat sink of claim 1, wherein at least one insert defines one or more projections along a surface that meets the heat sink.

7. The improved heat sink of claim 1, wherein at least one insert lies at a surface of the heat sink.

8. An improved heat sink, comprising:
a heat sink of aluminum or an aluminum alloy; and
one or more inserts of copper or a copper alloy molded into the heat sink.

9. A method of molding a heat sink with improved thermal performance, wherein the molding takes place at a molding temperature, comprising:
providing a molding cavity that defines the heat sink;
inserting into the cavity one or more inserts of a material with a relatively high conductivity and that is at least substantially solid at the molding temperature;
providing into the cavity with the one or more inserts a molten heat sink material having a conductivity lower than that of the one or more inserts; and
allowing the molten material to cool and harden, to create the heat sink.

10. The method of claim 9, wherein at least one insert lies at a surface of the heat sink.

11. The method of claim 9, wherein the heat sink material is aluminum or an alloy thereof.

12. The method of claim 9, wherein the insert material is copper or an alloy thereof.

13. The method of claim 9, wherein at least one insert defines one or more projections along a surface that meets the heat sink.
